(19) United States
(12) Patent Application Publication
(10) Pub. No.: US 2013/0015557 A1
(43) Pub. Date: Jan. 17, 2013

(54) SEMICONDUCTOR PACKAGE INCLUDING AN EXTERNAL CIRCUIT ELEMENT

(71) Applicants: Zhiping Yang, Cupertino, CA (US); Jie Xue, San Ramon, CA (US); Jovica Savic, Downers Grove, IL (US); Li Li, San Ramon, CA (US)

(72) Inventors: Zhiping Yang, Cupertino, CA (US); Jie Xue, San Ramon, CA (US); Jovica Savic, Downers Grove, IL (US); Li Li, San Ramon, CA (US)

(21) Appl. No.: 13/181,899

(22) Filed: Jul. 13, 2011

(51) Int. Cl. H01L 29/02; H01L 21/02

(52) U.S. Cl. 257/532; 438/381; 257/E29.002; 257/E21.008

(57) ABSTRACT

Circuit elements such as DC blocking capacitors used in communication such as a serial communication link between two or more electrical components are disposed in pre-existing openings in a support structure that supports at least one of the two electrical components. The openings may be plated and used for signal transmission from the one electrical component to a printed circuit board (PCB) supporting the substrate. The DC blocking capacitors may be oriented substantially vertically, and a non-conducting material may be disposed in each opening in the substrate such that the non-conducting material at least partially surrounds and fixes the orientation of the DC blocking capacitor disposed in the opening.

### FIELD

The present embodiments relate to a semiconductor package including an external circuit element.

### BACKGROUND

High-speed serial links may be used to transfer data signals between two or more (e.g., two) electrical components (e.g., semiconductor devices) such as, for example, application-specific integrated circuits (ASICs). The transferred data signals may be direct current-balanced (DC-balanced) signals to avoid voltage imbalance problems between the connected semiconductor devices (e.g., the semiconductor devices may have different DC voltage levels). In order to isolate DC bias voltages of the two semiconductor devices, DC blocking capacitors may be electrically connected to the semiconductor devices, between the semiconductor devices. Using the DC blocking capacitors, the alternating current (AC) portion of the transferred data signals may pass through while the DC portion of the transferred data signals may be blocked.

### BRIEF DESCRIPTION OF THE DRAWINGS

FIG. 1 illustrates a perspective view of one embodiment of a computer system including two electrically connected semiconductor packages;

FIG. 2 illustrates a front view of one embodiment of the computer system of FIG. 1;

FIG. 3 illustrates a cross-section view of one embodiment of the computer system of FIGS. 1 and 2;

FIG. 4 illustrates a cross-section view of one embodiment of a computer system including two electrically connected semiconductor packages; and

FIG. 5 illustrates a flow chart of one embodiment of manufacturing a semiconductor package.

### DETAILED DESCRIPTION OF THE DRAWINGS

### Overview

Circuit elements that are operable to block or substantially block direct current (DC), such as DC blocking capacitors used in high-speed serial links, may be placed vertically inside of non-plated through holes of a semiconductor package substrate, an interposer, or a printed circuit board (PCB). The non-plated through holes are pre-existing, so additional space is not used on the PCB to electrically connect the DC blocking capacitors to other devices, and no extra discontinuity or crosstalk is added in the high-speed signal.

In order to decrease the amount of board space used, circuit elements such as DC blocking capacitors used in a serial communication link between two or more electrical components are disposed in pre-existing openings in a support structure (e.g., a substrate) that supports at least one of the two electrical components; the openings are otherwise plated and used for signal transmission from the one electrical component to a PCB supporting the substrate. The DC blocking capacitors may be oriented substantially vertically, and a non-conducting material may be disposed in each opening in the substrate such that the non-conducting material at least partially surrounds and fixes the orientation of the DC blocking capacitor disposed in the opening. The number of vias in the PCB is decreased, thus also decreasing discontinuities and cross-talk in the serial communication link.

In one embodiment, an apparatus includes a substrate having a substrate core. The substrate core includes a first surface, a second surface that opposes the first surface, and a third surface, the third surface at least partly defining an opening. The opening extends at least partially between the first surface to the second surface of the substrate core. The apparatus also includes a semiconductor device supported by the substrate and a circuit element disposed in the opening in the substrate core. The circuit element is electrically connected to the semiconductor device. The circuit element may be operable to completely or substantially block DC current, such as DC current that is output from the semiconductor device and/or another semiconductor device, from travelling through the opening.

In another embodiment, an apparatus includes a first electrical component. The first electrical component includes a support structure including a core layer having a first surface, a second surface that opposes the first surface, and a third surface, the third surface at least partly defining an opening. The opening extends at least partially between the first surface and the second surface of the core layer. The first electrical component also includes a first electrical device electrically connected to the support structure and a circuit element disposed in the opening in the core layer of the support structure. The apparatus also includes a second electrical component. The second electrical component includes a second electrical device in electrical communication with the first electrical device via the support structure and the circuit element.

In yet another embodiment, a method includes forming an opening in a support structure. The support structure is operable to support a semiconductor device. The method also includes disposing a circuit element in the opening in the support structure such that a longitudinal axis of the circuit element is substantially parallel to a surface at least partly defining the opening. The method includes filling the opening in the support structure with an electrically non-conductive filling material and electrically connecting the semiconductor device to the circuit element.

### Example Embodiments

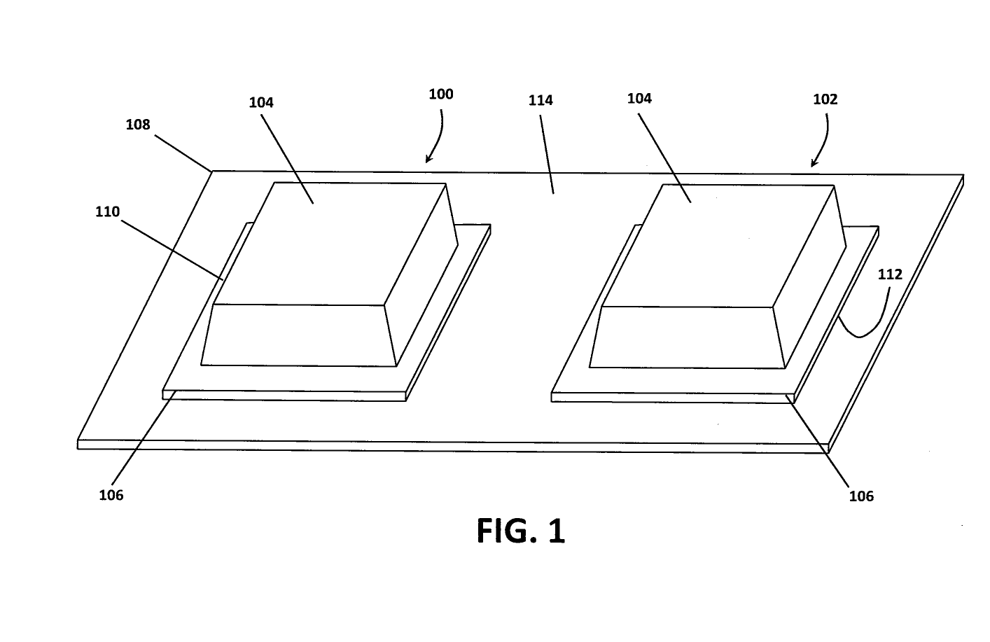

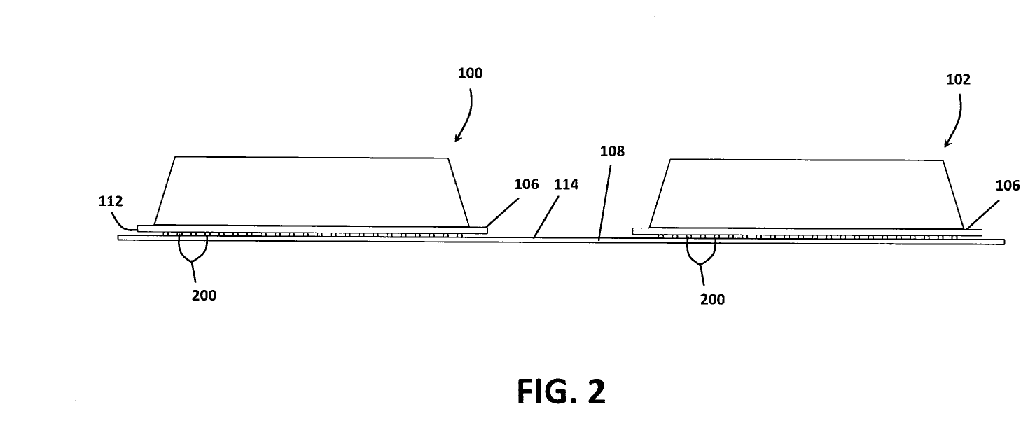

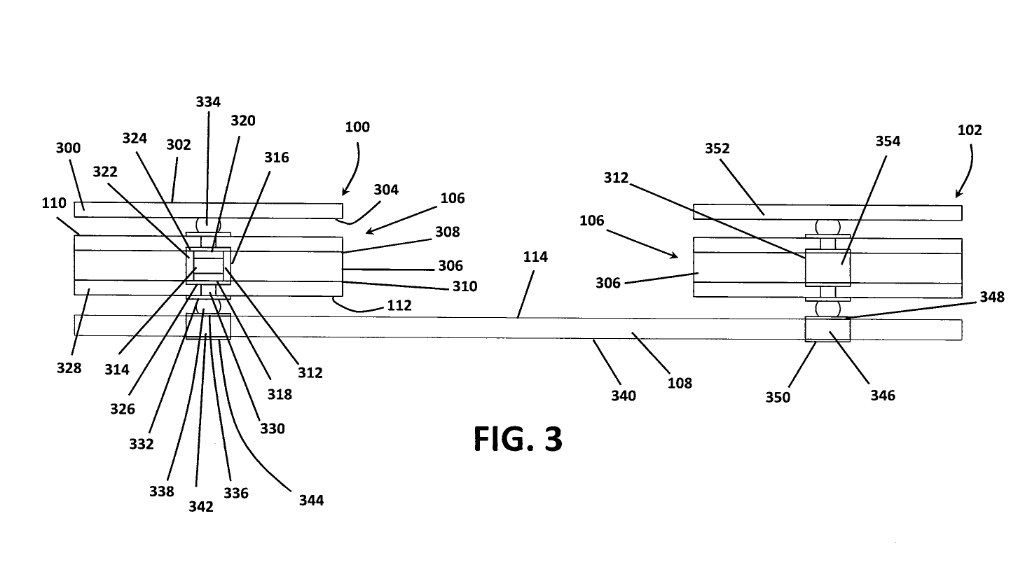

FIG. 1 illustrates a perspective view of one embodiment of a computer system including a first electrical component 100 (e.g., a first semiconductor package) and a second electrical component 102 (e.g., a second semiconductor package). Each of the first and second semiconductor packages 100 and 102 includes a molded casing 104, in which a semiconductor device (shown in FIGS. 2 and 3) is embedded. The semiconductor devices may be application-specific integrated circuits (ASICs), microprocessors, DRAM, flash memory, other devices or a combination thereof. The molded casings 104 are made of any number of materials including, for example, an epoxy-based resin material and have any shape. In one embodiment, the first semiconductor package 100 and/or the second semiconductor package 102 may not include the molded casings 104. The first and second semiconductor packages 100 and 102 may include a metal lid above the respective semiconductor devices.

The first and second semiconductor packages 100 and 102 each include a substrate 106 that supports the respective semiconductor device and the molded casing 104. The first and second semiconductor packages 100 and 102 may or may not be supported by and electrically connected to a printed circuit board (PCB) 108 (e.g., the first semiconductor package 100 may be supported by another semiconductor package or an interposer). The substrates 106 each include a first surface 110 (e.g., a top surface) and a second surface 112 (e.g., a bottom surface). The first surface 110 of each substrate 106 may support and be electrically connected to the respective semiconductor device, while a first surface 114 (e.g., a top surface) of the PCB 108 may support and be electrically connected to the second surfaces 112 of the substrates 106.

The substrates 106 may be organic substrates 106 (i.e., the substrate is made from a polymeric material) such as, for example, bismaleimide triazine-based (BT-based) substrates 106. Other substrates, such as, for example, insulated metal substrates and ceramic substrates, may be used for the substrates 106. In one embodiment, the first semiconductor package 100 and/or the second semiconductor package 102 do not include the substrate 106 and are directly attached to the PCB 108. In another embodiment, the first semiconductor package 100 and the second semiconductor package 102 are supported by different PCBs. The first semiconductor package 100 and the second semiconductor package 102 may be located in different computer systems.

FIG. 2 illustrates a front view of one embodiment of a computer system with the first and second semiconductor packages 100 and 102 of FIG. 1 or different semiconductor packages, each with a ball grid array. The bottom surface 112 of each substrate 106 may be attached to the top surface 114 of the PCB 108. The bottom surface 112 of each substrate 106 includes an array of solder balls 200 (e.g., a ball grid array (BGA)) used to conduct electrical signals from the first or second semiconductor package 100 or 102 to the PCB 108. Each BGA 200 is attached to corresponding contact pads on the PCB 108 using, for example, reflow soldering. Other arrangements of conductive materials such as, for example, an array of conductive pins may be provided on the bottom surface 112 of each substrate 106 to conduct electrical signals to and/or from the first and second semiconductor packages 100 and 102 from and/or to the PCB 108. The PCB 108 may include internal or external conductive routing layers (not shown) that electrically connect the first semiconductor package 100 to the second semiconductor package 102. Alternatively, the first semiconductor package 100 may be electrically connected to the second semiconductor package 102 with traces on one or more external surfaces of the PCB 108.

FIG. 3 illustrates a cross-section view of a portion of one embodiment of the computer system of FIGS. 1 and 2 or a different computer system. The first semiconductor package 100 includes a first semiconductor device 300 and the substrate 106. The molded casing 104 at least partly surrounds the first semiconductor device 300 (shown with the molded casing removed in FIG. 3). The first semiconductor device 300 includes an active side 302 and a passive side 304 that may be opposite the active side 302. The active side 302 may be embedded in the molded casing 104, for example. Alternatively, the active side 302 may face the substrate 106. The active side 302 of the first semiconductor device 300 may include a plurality of layers that forms an integrated circuit. In one embodiment, the active side 302 may include a plurality of stacked integrated circuits that are interconnected. The integrated circuit may include any number and combination of electrical components including, for example, transistors, memristors, resistors, capacitors and/or inductors. An outermost layer of the plurality of layers that forms the integrated circuit of the active side 302 may be a passivation layer. The passivation layer may be silicon oxide, for example. The first semiconductor device 300 may be made of any number of semiconductor materials including, for example, silicon, gallium arsenide or silicon carbide. The first semiconductor device 300 may be, for example, an application-specific integrated circuit (ASIC) or a microprocessor.

The first semiconductor device 300 may include a plurality of through vias (not shown) that pass at least partly though the first semiconductor device 300, connecting the integrated circuit of the active side 302 to the passive side 304 of the first semiconductor device 300. The through vias may extend in a direction generally perpendicular to the active side 302 and/or the passive side 304 of the first semiconductor device 300. “Generally” allows for other angles while still extending in a direction away from the active side 302 and/or the passive side 304 of the first semiconductor device 300. The through vias may be filled with any number of electrically conductive materials (e.g., an electrically conductive plating) including, for example, copper. The through vias may be located anywhere on the first semiconductor device 300 including, for example, at the perimeter of the first semiconductor device 300 or internal to the perimeter of the first semiconductor device 300.

The first semiconductor device 300 may also include bonding pads (not shown) deposited on the passive side 304 of the first semiconductor device 300. The bonding pads are connected to the electrically conductive plating of the through vias. The bonding pads may be made of a different material than or the same material as the electrically conductive plating of the through vias (e.g., aluminum or copper). The bonding pads may be formed as a single piece with the electrically conductive plating of the through vias. The bonding pads are deposited using electroplating or electroless plating, for example. The bonding pads may also be adhered to the electrically conductive plating of the through vias with solder, for example. In one embodiment, the passive side 304 of the first semiconductor device 300 does not include bonding pads, and the active side 302 of the first semiconductor device 300 faces the substrate 106. The active side 302 of the first semiconductor device 300 may be electrically connected to the substrate 106 with solder bumps (e.g., C4 solder bumps), for example.

The substrate 106 of the first semiconductor device 300 includes a substrate core 306. The substrate core 306 includes a first surface 308, a second surface 310, and a plurality of openings 312 (e.g., a plurality of non-plated through holes; one shown in FIG. 3). The substrate core 306 may be a bismaleimide triazine-based (BT-based) substrate core, for example. The substrate core 306 may be any number of shapes including, for example, rectangular. Each opening 312 of the plurality of openings may extend from the first surface 308 to the second surface 310 of the substrate core 306 in a direction generally perpendicular to the first surface 308 and/or the second surface 310 of the substrate core 306 (e.g., vertically). “Generally” allows for other angles while still extending in a direction away from the first surface 308 and/or the second surface 310 of the substrate core 306. In one embodiment, each opening 312 of the plurality of openings is larger at the first surface 308 than at the second surface 310. In another embodiment, the plurality of openings 312 may extend from the first surface 308 or the second surface 310 of the substrate core 306, at least partly through the substrate core 306. The plurality of openings 312 may be any number of shapes including v-shaped, conical or cylindrical, for example.

A circuit element 314 (e.g., a DC blocking capacitor) may be disposed in each opening 312 of the plurality. The circuit element 314 may also be a resistor or an inductor, for example. An opening 312 may be sized and shaped such that at least part of the circuit element 314 abuts a surface 316 that at least partly defines the opening 312 (e.g., a semi-tight fit; the circuit element 314 is not shown abutting the surface 316 in FIG. 3 for clarity). The circuit element 314 may be disposed in the opening 312 such that the surface 316 that at least partly defines the opening 312 at least partly surrounds the circuit element 314. The DC blocking capacitor 314 may be disposed in the opening 312 such that a first end 318 (e.g., an input) of the DC blocking capacitor 314 is adjacent to the second surface 310 of the substrate core 306, and a second end 320 (e.g., an output) of the blocking capacitor 314 is adjacent to the first surface 308 of the substrate core 306. Electrical signals may flow in one direction through the DC blocking capacitor (e.g., from the first end 318 to the second end 320 or from the second end 320 to the first end 318) or in both directions through the DC blocking capacitor 314 (e.g., from the first end 318 to the second end 320 and from the second end 320 to the first end 318). In one embodiment, the DC blocking capacitor 314 is disposed in the opening 312 such that a longitudinal axis of the DC blocking capacitor 314 (e.g., extending from the input 318 to the output 320 of the DC blocking capacitor 314) is substantially perpendicular to the first surface 308 and/or the second surface 310 of the substrate core 306. Alternatively or additionally, the DC blocking capacitor 314 may be disposed in the opening 312 such that the longitudinal axis of the DC blocking capacitor 314 is substantially parallel to the surface 316 that at least partly defines the opening 312. In other words, the longitudinal axis of the blocking capacitor 314 may extend vertically between the first surface 308 and the second surface 310 of the substrate core 306. In other embodiments, the DC blocking capacitor 314 may be in different orientations relative to the surface 316 (e.g., substantially perpendicular to the surface 316). The DC blocking capacitor 314 may be disposed in the opening 312 to be completely surrounded by the surface 316 such that the DC blocking capacitor 314 does not extend out of the opening 312 beyond the first surface 308 and the second surface 310. Alternatively, the DC blocking capacitor 314 may be disposed in the opening 312 to be partially surrounded by the surface 316 such that a part of the DC blocking capacitor 314 extends out of the opening 312 beyond one or both of the first surface 308 and the second surface 310.

An electrically non-conductive material 322 (e.g., an epoxy) may be disposed in each opening 312 of the plurality to fix the orientation of the DC blocking capacitor 314 relative to the surface 316. The epoxy 322 may be disposed in the opening 312 such that the epoxy 322 at least partially surrounds the DC blocking capacitor 314. In one embodiment, the epoxy 322 may be applied (e.g., laminated) to the first surface 308 and the second surface 310 of the substrate core 306 and allowed to flow into the plurality of openings 312. Openings (e.g., micro vias; not shown) may be formed (e.g., drilled) in the epoxy 322 disposed on the first surface 308 and the second surface 310 of the substrate core 306, adjacent to the input 318 and the output 320 of the DC blocking capacitor 314. The micro vias in the epoxy 322 may be filled with any number of electrically conductive materials (e.g., an electrically conductive plating) including, for example, copper.

A first layer of electrically conductive material 324 (e.g., a first layer of copper) may be disposed (e.g., plated) on or adjacent to the first surface 308 of the substrate core 306, and a second layer of electrically conductive material 326 (e.g., a second layer of copper) may be disposed (e.g., plated) on or adjacent to the second surface 310 of the substrate core 306. The first layer of conductive material 324 and the second layer of conductive material 326 may be any number of electrically conductive materials including, for example, aluminum or copper. The first layer of copper 324 and the second layer of copper 326 may be etched to form a circuit (e.g., traces).

Insulating layers 328 may be disposed (e.g., laminated) on or adjacent to the first surface 308 and/or the second surface 310 of the substrate core 306. The insulating layers 328 may be any number of dielectric materials including, for example, glass reinforced epoxy. The insulating layers 328 may be attached (e.g., laminated) to the substrate core 306 and/or each other using an epoxy, for example. The insulating layers 328 may include vias 330 filled (e.g., plated) with the same or a different electrically conducting material than the first and second layers of electrically conducting material 324 and 326 (e.g., copper).

The substrate 106 may also include one or more additional layers of electrically conductive material (e.g., additional layers of copper) that abut or are adjacent to at least one insulating layer 328. The additional layers of copper may be etched to form additional circuits (e.g., traces) within or on the substrate 106.

The first surface 110 and the second surface 112 of the substrate 106 may include bonding pads 332 that abut the copper plated vias 330. The bonding pads 332 may be made of a different or the same material as the plating of the vias 330 (e.g., aluminum or copper). The bonding pads 332 may be formed as a single piece with the plating of the vias 330. The bonding pads 332 may be deposited using electroplating or electroless plating, for example. The bonding pads 332 may also be adhered to the plating of the vias 330 with solder, for example.

The bonding pads on the passive side 304 of the first semiconductor device 300 may be attached to the bonding pads 332 on the first surface 110 of the substrate 106 using an array of solder balls 334 (e.g., a ball grid array (BGA)) attached to the passive side 304 of the first semiconductor device 300, for example. Other arrangements of conductive materials such as, for example, an array of conductive pins may be provided on the passive side 304 of the first semiconductor device 300 to conduct electrical signals to and/or from the first semiconductor device. The BGA 334 may be attached to the bonding pads 332 on the first surface 110 of the substrate 106 using reflow soldering, for example. The BGA 334 may be used to conduct electrical signals from the substrate 106 to the first semiconductor device 300 and/or from the first semiconductor device 300 to the substrate 106.

The bonding pads 332 on the second surface 112 of the substrate 106 may be attached to bonding pads 336 on the top surface 114 of the PCB 108 using an array of solder balls 338 (e.g., a ball grid array (BGA); the BGA 338 may be the same or different than the BGA 200 shown in FIG. 2) attached to the second surface 112 of the substrate 106, for example. The BGA 338 may be attached to the bonding pads 336 on the top surface 114 of the PCB 108 using reflow soldering, for example. The BGA 338 may be used to conduct electrical signals from the PCB 108 to the substrate 106 of the first semiconductor package 100 and/or from the substrate 106 of the first semiconductor package 100 to the PCB 108.

The PCB 108 may include the first surface 114 and a second surface 340. The PCB 108 may include a first plurality of vias 342 (one shown) filled (e.g., plated) with an electrically conducting material such as, for example, copper. Each via of the first plurality of vias 342 may extend from the first surface 114 to the second surface 340 of the PCB 108. The bonding pads 336 on the top surface 114 of the PCB 108 may abut corresponding vias of the plurality of copper plated vias 342. Alternatively, the PCB 108 may not include the bonding pads 336, and the BGA 338 may be attached directly to the first plurality of copper plated vias 342. The PCB 108 may also include bonding pads 344 on the second surface 340 of the PCB 108. The bonding pads 344 may also abut the first plurality of copper plated vias 342. The bonding pads 344 may be made of a different or the same material as the plating of the first plurality of vias 342 (e.g., aluminum or copper).

The PCB 108 may include one or more layers of electrically conducting material (e.g., copper; not shown) on the first surface 114 of the PCB 108, the second surface 340 of the PCB 108, and/or within the PCB. The one or more layers of copper may be etched to form circuits (e.g., traces) on and/or in the PCB 108. The one or more layers of copper on and/or in the PCB 108 may electrically connect the first semiconductor package 100 to the second semiconductor package 102 via a second plurality of vias 346 (one shown) filled (e.g., plated) with an electrically conducting material such as, for example, copper. Each via of the second plurality of vias 346 may extend from the first surface 114 to the second surface 340 of the PCB 108. The PCB 108 may include bonding pads 348 on the first surface 114 and bonding pads 350 on the second surface 340 of the PCB 108; the bonding pads 348 on the first surface 114 and the bonding pads 350 on the second surface 340 may abut corresponding vias of the second plurality of copper plated vias 346.

The second semiconductor package 102 includes a second semiconductor device 352 and the substrate 106. The second semiconductor device 352 may be attached and electrically connected to the substrate 106 in the same or a similar way as discussed above for the first semiconductor package 100. Also, the second semiconductor package 102 may be attached and electrically connected to the PCB 108 in the same or a similar way as discussed above for the first semiconductor package 100. In other embodiments, the second semiconductor package 102 may include different components and/or more or fewer components than the first semiconductor package 100.

Except for the plurality of openings 312, the substrate 106 of the second semiconductor package 102 may be configured in the same or a similar way as discussed above for the first semiconductor package 100. The plurality of openings 312 in the substrate 106 of the second semiconductor package 102 may be filled (e.g., plated) with an electrically conductive material 354 (e.g., copper plating) to transmit signals from the second semiconductor device 352 to the first semiconductor device 300 and/or from the first semiconductor device 300 to the second semiconductor device 352. The substrates 106 of the first and second semiconductor package 100 may be the same or different shapes, sizes and/or materials.

In other embodiments, the second semiconductor package 102 includes more or fewer openings 312, more or fewer insulating layers 328 disposed on or adjacent the substrate core 306 and/or more or fewer layers of electrically conducting material than the first semiconductor package 100. The first electrical component 100 and/or the second electrical component 102 may not be semiconductor packages. The first electrical component 100 and the second electrical component 102 may be any number of electrical components including, but not limited to, an integrated circuit, such as a field programmable gate array (FPGA), an application specific integrated circuit (ASIC), or a radio frequency (RF) integrated circuit, a power supply, a memory device, a controller, digital logic, one or more transistors, or one or more diodes.

Semiconductor packages may include the same number, or different numbers, of openings in a substrate supporting a semiconductor device as the number of openings 312 in the present embodiments (e.g., two openings for each differential pair). In some examples, the openings may be plated with a conductive material (e.g., copper) and used to transmit signals from the semiconductor device to and/or from the PCB. Accordingly, the semiconductor packages 100 of the present embodiments may utilize already existing through-holes to house the DC blocking capacitors 314. By utilizing already existing through-holes, bonding pads and vias used to electrically connect the DC blocking capacitors to signal traces within the PCB may not be needed. Also, PCB space used for the DC blocking capacitors may not be needed; this may increase the density of the semiconductor packages of the present embodiments and reduce the size and cost of the PCB 108 in the computer system.

In some configurations, the vias and bond pads in and on the PCB used to electrically connect the DC blocking capacitors to the signal traces within the PCB may cause cross-talk and signal reflection (e.g., noise) within a serial link between two electrical components (e.g., two semiconductor packages). By positioning the DC blocking capacitors 314 within the already existing plurality of openings 312 in the substrate 106, cross-talk and signal reflections may be reduced, thus increasing high-speed serial link performance.

Positioning the DC blocking capacitors 314 in the plurality of openings 312 such that the longitudinal axes of the DC blocking capacitors 314 are generally parallel to the surfaces 316 that at least partly define the plurality of openings 312 may minimize the length of the signal path from the first semiconductor device 300 to the PCB 108. This may also reduce the impedance between the first semiconductor device 300 and the PCB 108 and thus, reduce the parasitic losses between the first semiconductor device 300 and the PCB 108. By positioning the DC blocking capacitors 314 in the already existing plurality of openings 312 in the substrate 106, the DC blocking capacitors 314 may not take up additional board space on or in the substrate 106 and may not affect the positioning of signal traces and other components within the substrate 106.

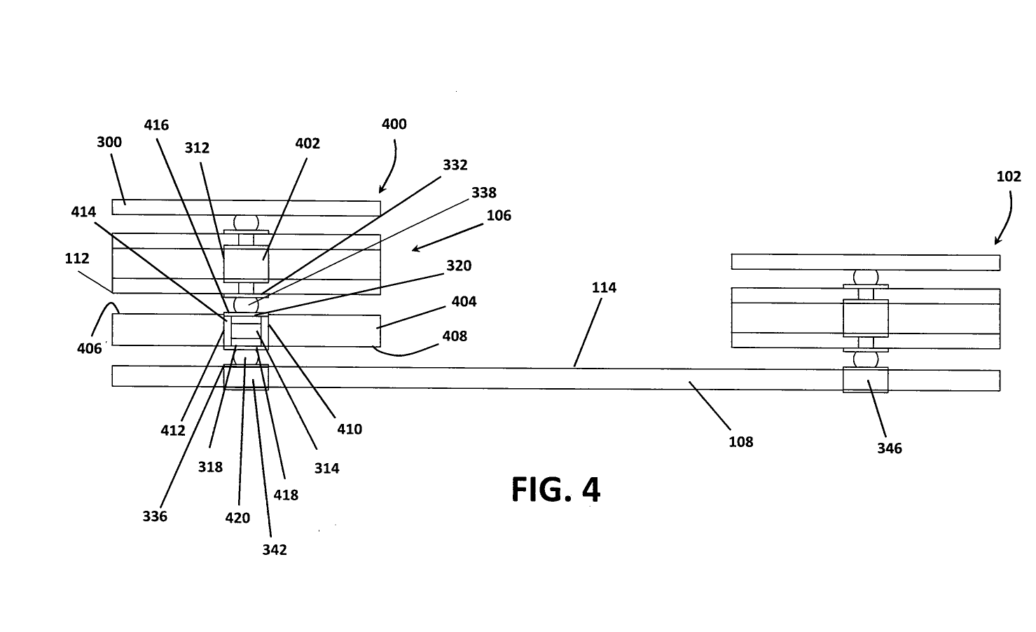

FIG. 4 illustrates a cross-section view of another embodiment of a system including two electrically connected semiconductor packages. The system includes a first semiconductor package 400 and the second semiconductor package 102 of FIGS. 1-3. The first semiconductor package 400 includes the substrate 106 that supports and is electrically connected to the first semiconductor device 300. In the embodiment shown in FIG. 4, the DC blocking capacitors 314 are not disposed in the plurality of openings 312 in the substrate 106. The plurality of openings 312 are instead filled (e.g., plated) with an electrically conducting material 402 such as, for example, copper.

The substrate 106 is supported by an interposer 404, for example. The interposer 404 may be made of any number of dielectric materials including, for example, glass reinforced epoxy. The interposer 404 may include a first surface 406, a second surface 408 and surfaces 410 that at least partly define a plurality of openings 412 (one shown). Each opening 412 of the plurality may extend from the first surface 406 to the second surface 408 of the interposer 404 in a direction generally perpendicular to the first surface 406 and/or the second surface 408 of the interposer 404 (e.g., vertically). “Generally” allows for other angles while still extending in a direction away from the first surface 406 and/or the second surface 408 of the interposer 404. In one embodiment, each opening 412 of the plurality of openings is larger at the first surface 408 than at the second surface 410. The interposer 404 may be any number of shapes including, for example, rectangular. The plurality of openings 412 may be cylindrical, for example.

A circuit element 314 (e.g., a DC blocking capacitor) may be disposed in each opening 412 of the plurality. The circuit element 314 may also be a resistor or an inductor, for example. An opening 412 may be sized and shaped such that at least part of the DC blocking capacitor 314 abuts the surface 410 that at least partly defines the opening 412 (e.g., a semi-tight fit). The DC blocking capacitor 314 may be disposed in the opening 412 such that the input 318 of the DC blocking capacitor 314 is adjacent to the second surface 408 of the interposer 404, and the output 320 of the DC blocking capacitor 314 is adjacent to the first surface 406 of the interposer 404. In one embodiment, the DC blocking capacitor 314 is disposed in the opening 412 such that a longitudinal axis of the DC blocking capacitor 314 (e.g., extending from the input 318 to the output 320 of the DC blocking capacitor 314) is substantially parallel to the surface 410 that at least partly defines the opening 412. In other words, the longitudinal axis of the blocking capacitor 314 may extend substantially vertical between the first surface 406 and the second surface 408 of the interposer 404. In other embodiments, the DC blocking capacitor 314 may be in different orientations relative to the surface 410.

An electrically non-conductive material 414 (e.g., an epoxy) may be disposed in each opening 412 of the plurality to fix the orientation (e.g., vertical orientation) of the blocking capacitor 314 within the opening 412. The epoxy 414 may be disposed in the opening 412 such that the epoxy 414 at least partially surrounds the DC blocking capacitor 314. In one embodiment, the epoxy 414 may be applied (e.g., laminated) to the first surface 406 and the second surface 408 of the interposer 404 and allowed to flow into the plurality of openings 412. Openings (e.g., micro vias; not shown) may be formed (e.g., drilled) in the epoxy 414 disposed on the first surface 406 and the second surface 408 of the interposer 404, adjacent to the input 318 and the output 320 of the DC blocking capacitor 314. The micro vias in the epoxy 414 may be filled with any number of electrically conductive materials (e.g., an electrically conductive plating) including, for example, copper.

A first layer of electrically conductive material 416 may be disposed (e.g., plated) on or adjacent to the first surface 406 of the interposer 404, and a second layer of electrically conductive material 418 may be disposed (e.g., plated) on or adjacent to the second surface 408 of the interposer 404. The first layer of electrically conductive material 416 may abut or be adjacent to the output 320 of the DC blocking capacitor 314, and the second layer of electrically conductive material 418 may abut or be adjacent to the input 318 of the DC blocking capacitor 314. In one embodiment, the first layer of electrically conductive material 416 and the second layer of electrically conductive material 418 may be electrically connected to the output 320 and the input 318 of the DC blocking capacitor 314, respectively, through the plated micro vias in the epoxy 414. The first layer of conductive material 416 and the second layer of conductive material 418 may be any number of electrically conductive materials including, for example, copper or aluminum. The first layer of copper 416 and the second layer of copper 418 may be bonding pads, for example. The first layer of copper 416 and the second layer of copper 418 may be etched to form a circuit (e.g., traces).

Insulating layers may be disposed (e.g., laminated) on or adjacent to the first surface 406 and/or the second surface 408 of the interposer 404. The additional insulating layers may be any number of dielectric materials including, for example, glass reinforced epoxy. The insulating layers may be attached (e.g., laminated) to the interposer 404 and/or each other using an epoxy, for example. The insulating layers may include vias filled (e.g., plated) with the same or a different electrically conducting material than the first and second layers of electrically conducting material 416 and 418 (e.g., copper).

The interposer 404 may also include one or more additional layers of electrically conductive material (e.g., additional layers of copper) that abut or are adjacent to one or more of the insulating layers. The additional layers of copper may be etched to form additional circuits (e.g., traces) within or on the interposer 404.

The bonding pads 332 on the second surface 112 of the substrate 106 may be attached to the first layer of copper 416 (e.g., bonding pads) of the interposer 404 using the BGA 338 attached to the second surface 112 of the substrate 106, for example. The BGA 338 may be attached to the first layer of copper 416 of the interposer 404 using reflow soldering, for example. The BGA 338 may be used to conduct electrical signals from the interposer 404 to the substrate 106 of the first semiconductor package 100 and/or from the substrate 106 to the interposer 404 of the first semiconductor package 100.

The second layer of copper 418 (e.g., bonding pads) of the interposer 404 may be attached to the bonding pads 336 on the top surface 114 of the PCB 108 using an array of solder balls 420 (e.g., a ball grid array (BGA)) attached to the second layer of copper 418 of the interposer 404, for example. The BGA 420 may be attached to the bonding pads 336 on the top surface 114 of the PCB 108 using reflow soldering, for example. The BGA 420 may be used to conduct electrical signals from the PCB 108 to the interposer 404 of the first semiconductor package 100 and/or from the interposer 404 of the first semiconductor package 100 to the PCB 108.

In the embodiment shown in FIG. 4, the interposer 404 houses the DC blocking capacitors 314. In another embodiment, the first semiconductor package 400 does not include an interposer 404, and the DC blocking capacitors 314 are disposed in the first plurality of vias 342 or the second plurality of vias 346 in the PCB 108. The first plurality of vias 342, for example, may be filled with an electrically non-conductive material (e.g., an epoxy) to fix the orientation (e.g., vertical orientation) of the blocking capacitors 314 within the first plurality of vias 342. The epoxy may be disposed in the first plurality of vias 342 such that the epoxy at least partially surrounds the blocking capacitors 314.

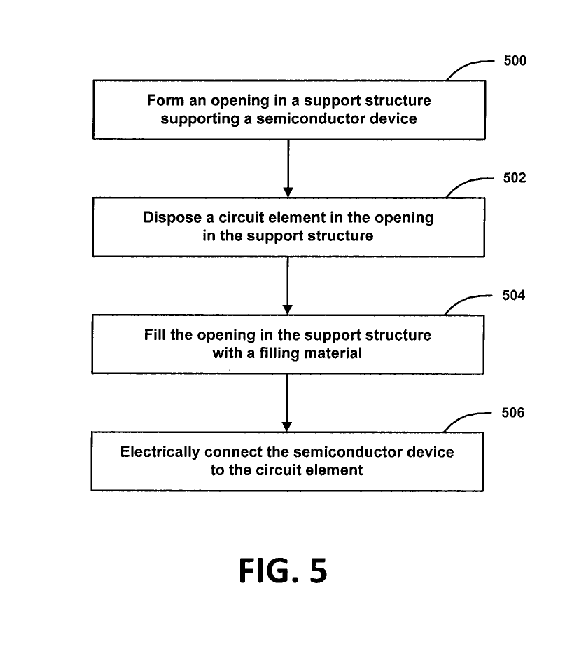

FIG. 5 illustrates a flow chart of one embodiment of manufacturing the semiconductor package of FIGS. 1-4 or a different semiconductor package. The method is implemented in the order shown, but other orders may be used. Additional, different, or fewer acts may be provided.

In act 500, an opening is formed in a support structure. The support structure is operable to support a semiconductor device. The opening may be created in any number of ways including, for example, with a drill or saw, by pressing, or by forming the support structure with the opening. The opening may be formed using control depth drilling. A single drill bit or a plurality of drill bits having different diameters may be used. In one embodiment, more than one opening is formed in the support structure. The one or more openings may extend at least partly between a first surface (e.g., a top surface) of the support structure and a second surface (e.g., a bottom surface) of the support structure. In one embodiment, the one or more openings extends from a first surface (e.g., a top surface) of a core layer of the support structure to a second surface (e.g., a bottom surface) of the core layer. Where an opening extends partly between the first surface and the second surface, for example there is an opening at the first surface but not at the second surface, a platform may be formed at the second surface on which the circuit element, such as the DC blocking capacitor, may be disposed. Alternatively or in addition, where the opening extends partly between the first surface and the second surface, a hole, such as a vent hole, may extend through the platform. The one or more openings may extend in a direction generally perpendicular to the top surface of the support structure, the bottom surface of the support structure, the top surface of the core layer, and/or the bottom surface of the core layer (e.g., vertically). Alternatively, the one or more openings may extend in a direction that is at an angle less than or greater than ninety degrees to the first surface and/or the second surface of the core layer. In one embodiment, each opening of the one or more openings may be larger at the first surface than the second surface. The support structure may be initially plugged and laser drilling may be used to form the one or more openings. The opening at the second surface may be smaller than a width of the circuit element. The smaller size of the opening at the second surface may prevent the circuit element from falling out of or passing through the support structure when placed in the support structure through the opening at the first surface. The support structure may be a substrate, an interposer or a printed circuit board (PCB), for example. The support structure may be a bismaleimide triazine-based (BT-based) substrate, for example. The plurality of openings may be any number of shapes including, for example, conical or cylindrical.

A first portion of the one or more openings may be filled (e.g., plated) with an electrically conducting material such as, for example, copper, and a second portion of the one or more openings may not be plated (e.g., unplated openings) with the electrically conducting material. The first portion of the one or more openings may be plated using electroplating or electroless plating, for example. The unplated openings may be filled with a dry film, for example, to prevent the unplated openings from being filled with the electrically conducting material during the plating process.

In act 502, a circuit element is disposed in the one of the openings in the support structure. The circuit element may be disposed through some or all of the openings in the support structure. The openings may be shaped and sized such that at least part of the circuit element abuts a surface at least partly defining one of openings in the support structure. In one embodiment, the minimum diameter of the opening is approximately equal to a diameter of circuit element to fixedly maintain the circuit element in the opening using, for example, friction fit, snap fit, wedging, or any other form of coupling mechanism to maintain the circuit element disposed in the opening. The circuit element may be a direct current (DC) blocking capacitor. In other embodiments, the circuit element may be a resistor or an inductor, for example.

The circuit element may be disposed in the opening in the support structure such that a longitudinal axis extending between an input and an output of the circuit element is generally parallel to a surface at least partly defining the opening in the support structure and/or generally perpendicular to the top surface of the support structure and/or the bottom surface of the support structure. The circuit element may be disposed in the opening in the support structure such that the surface at least partly defining the opening in the support structure at least partly surrounds the circuit element (e.g., an end of the circuit element may be above the top surface of the core layer or below the bottom surface of the core layer). In one embodiment, the circuit element may be disposed in the opening in the substrate such that the longitudinal axis of the circuit element is vertical.

In one embodiment, the diameter of the opening in the support structure may be greater than the diameter of the circuit element. A film layer (e.g., a pressure/heat sensitive film) may be positioned over the opening and attached to the bottom surface of the support structure with pressure, heat and/or an adhesive, for example, such that the circuit element remains in the opening. The film layer may include a hole (e.g., a vent hole). The opening in the film layer may be concentric with the opening. The film layer may be made of any number of materials including, for example, an expoxy and/or an elastomer.

In act 504, the opening in the support structure is filled with a filling material (e.g., a paste). The filling material may be an electrically non-conducting material such as, for example, an epoxy. Other adhesives, for example, may be used as the filling material. The opening in the support structure may be filled with the filling material such that the circuit element is at least partly surrounded by the filling material. The filling material may act to fix the orientation (e.g., vertical orientation) of the circuit element within the opening in the support structure. In one embodiment, a layer of epoxy may be applied (e.g., laminated) to the top surface and/or the bottom surface of the core layer of the support structure. The epoxy may be allowed to flow into the opening (or plurality of openings) such that the epoxy at least partly surrounds the circuit element. Screen printing or screen printing under vacuum may be used to fill the opening in the support structure, for example. Some of the filling material may flow through the vent hole. The filling material may be dried and cured, and support structure may be planarized such that the film layer is removed.

In act 506, the semiconductor device is electrically connected to the circuit element. Openings (e.g., micro vias) may be formed (e.g., drilled) in the filling material in the opening, adjacent to the input and the output of the circuit element. The micro vias in the layers of epoxy may be filled with any number of electrically conductive materials (e.g., an electrically conductive plating) including, for example, copper.

One or more layers of electrically conductive material (e.g., copper or aluminum) may be disposed (e.g., plated) on or adjacent to the top surface and/or the bottom surface of the core layer of the support structure. The one or more layers of electrically conductive material may be etched to form a circuit (e.g., traces). The one or more layers of electrically conductive material may be disposed on or adjacent to the top surface and/or the bottom surface of the core layer of the support structure before or after the opening is formed in the support structure.

Insulating layers may be disposed (e.g., laminated) on or adjacent to the top surface and/or the bottom surface of the core layer of the support structure. The insulating layers may be any number of dielectric materials including, for example, Ajinomoto Build-Up Film (ABF) or pre-impregnated composite fibers (“pre-preg). The insulating layers may be attached (e.g., laminated) to the core layer and/or each other using an epoxy, for example. Vias may be formed (e.g., drilled) in the insulating layers, and the vias in the insulating layers may be filled (e.g., plated) with the same or a different electrically conducting material than the one or more layers of electrically conductive material (e.g., copper).

One or more additional layers of electrically conductive material (e.g., additional layers of copper) may be disposed (e.g., via electroless plating or electroplating) on or adjacent to at least one insulating layer. The additional layers of copper may be etched to form additional circuits (e.g., traces) within or on the support structure.

Bonding pads may be disposed (e.g., plated) on or adjacent to the top surface of the support structure and the bottom surface of the support structure, such that the bonding pads abut or are adjacent to the copper plated vias in the insulating layers or the input and the output of the circuit element. The bonding pads may be made of a different or the same electrically conducting material as the plating of the vias in the insulating layers (e.g., aluminum or copper). The bonding pads may be formed as a single piece with the plating of the vias in the insulating layers. The bonding pads may be deposited using electroplating or electroless plating, for example. The bonding pads may also be adhered to the plating of the vias in the insulating layers with solder, for example.

The bonding pads on the top surface of the support structure may be attached to bonding pads on the substrate or bonding pads on the semiconductor device (e.g., depending on whether the support structure is the PCB, the interposer or the substrate) using an array of solder balls (e.g., a ball grid array (BGA)) attached to the bonding pads on the substrate or the bonding pads on the semiconductor device. The BGA may be attached to the bonding pads on the top surface of the support structure using reflow soldering, for example, to electrically connect the support structure and the semiconductor device.

Various embodiments described herein can be used alone or in combination with one another. The foregoing detailed description has described only a few of the many possible implementations of the present invention. For this reason, this detailed description is intended by way of illustration, and not by way of limitation.

1. An apparatus comprising:
a substrate comprising a substrate core having a first surface, a second surface opposing the first surface, and a third surface, the third surface at least partly defining an opening, the opening extending at least partially between the first surface to the second surface of the substrate core;
a semiconductor device supported by the substrate; and
a circuit element disposed in the opening in the substrate core, the circuit element being electrically connected to the semiconductor device,
wherein the circuit element is operable to substantially block direct current outputted by the semiconductor device or another semiconductor device.

2. The apparatus of claim 1, further comprising a non-conductive material disposed in the opening in the substrate core,
wherein the non-conductive material at least partially surrounds the circuit element.

3. The apparatus of claim 2, wherein the non-conductive material is a non-conductive epoxy.

4. The apparatus of claim 1, wherein the circuit element is a capacitor.

5. The apparatus of claim 1, wherein the circuit element comprises a longitudinal axis, and
wherein the circuit element is disposed in the opening in the substrate core such that the longitudinal axis of the circuit element is substantially parallel to the third surface of the substrate core.

6. The apparatus of claim 1, wherein the circuit element is disposed in the opening in the substrate core such that the longitudinal axis of the circuit element is substantially perpendicular to the first surface or the second surface of the substrate core.

7. The apparatus of claim 1, further comprising a printed circuit board (PCB) coupled and electrically connected to the substrate, the semiconductor device being electrically connected to the PCB via the circuit element.

8. An apparatus comprising:
a first electrical component comprising:
a support structure comprising a core layer having a first surface, a second surface opposing the first surface, and a third surface, the third surface at least partly defining an opening, the opening extending at least partially between the first surface and the second surface of the core layer;
a first electrical device electrically connected to the support structure; and
a circuit element disposed in the opening in the core layer of the support structure; and
a second electrical component comprising:
a second electrical device in electrical communication with the first electrical device via the support structure and the circuit element,
wherein the circuit element is operable to substantially block direct current outputted by the second semiconductor device.

9. The apparatus of claim 8, wherein the circuit element is a capacitor.

10. The apparatus of claim 8, wherein the circuit element comprises a longitudinal axis, and
wherein the circuit element is disposed in the opening in the core layer of the support structure such that the longitudinal axis of the circuit element is substantially perpendicular to the first surface or the second surface of the core layer.

11. The apparatus of claim 8, wherein the support structure is a substrate, and
wherein the apparatus further comprises a printed circuit board (PCB), the PCB being electrically connected to the substrate of the first electrical component and being electrically connected to the second electrical component.

12. The apparatus of claim 8, wherein the support structure is a printed circuit board (PCB), the PCB being electrically connected to the second electrical component.

13. The apparatus of claim 12, wherein the first electrical component further comprises a first substrate, the PCB being electrically connected to the first substrate, the first substrate being electrically connected to the first electrical device, and
wherein the second electrical component further comprises a second substrate, the PCB being electrically connected to the second substrate, the second substrate being electrically connected to the second electrical device.

14. The apparatus of claim 8, further comprising a printed circuit board (PCB),
wherein the support structure is an interposer, the PCB being electrically connected to the interposer and the second electrical component.

15. The apparatus of claim 14, wherein the first electrical component further comprises a first substrate, the interposer being electrically connected to the first substrate, the first substrate being electrically connected to the first electrical device, and
wherein the second electrical component further comprises a second substrate, the PCB being electrically connected to the second substrate, the second substrate being electrically connected to the second electrical device.

16. A method comprising:
forming an opening in a support structure, the support structure operable to support a semiconductor device;
disposing a circuit element in the opening in the support structure such that a longitudinal axis of the circuit element is substantially parallel to a surface at least partly defining the opening;
filling the opening in the support structure with a an electrically non-conductive filling material; and
electrically connecting the semiconductor device to the circuit element,
wherein the circuit element is operable to substantially block direct current outputted by the semiconductor device or another semiconductor device.

17. The method of claim 16, wherein filling the opening in the support structure comprises filling the opening in the support structure with an electrically non-conductive epoxy.

18. The method of claim 16, wherein the support structure is a substrate.

19. The method of claim 18, wherein electrically connecting the semiconductor device to the circuit element comprises:
disposing a first layer of conductive material on or adjacent to a first surface of the substrate such that the first layer of conductive material is electrically connected to a first end of the circuit element; and
disposing a second layer of conductive material on or adjacent to a second surface of the substrate such that the second layer of conductive material is electrically connected to a second end of the circuit element.

20. The method of claim 19, wherein disposing the first layer of conductive material on or adjacent to the first surface of the substrate comprises plating a first layer of copper on or adjacent to the first surface of the substrate, and
wherein disposing the second layer of conductive material on or adjacent to the second surface of the substrate comprises plating a second layer of copper on or adjacent to the second surface of the substrate.
